(19) United States
(12) Patent Application Publication
(10) Pub. No.: US 2008/0252205 A1
(43) Pub. Date: Oct. 16, 2008

(54) Large Area Organic Diode Device and a Method of Manufacturing It

(75) Inventors: Edward Willem Albert Young, Eindhoven (NL); Herbert Lifka, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/088,433

(22) PCT Filed: Sep. 20, 2006
(86) PCT No.: PCT/IB2006/053406

§ 371 Date: Mar. 28, 2008

(30) Foreign Application Priority Data
Sep. 28, 2005 (EP) 05108973.8

(51) Int. Cl. H01L 51/52; C25D 5/02

(52) U.S. Cl. 313/504; 205/122

(57) ABSTRACT

An organic diode device (1) comprises an organic diode structure (2) having an anode layer (12), a cathode layer (13) and an organic layer (14). One of the anode layer (12) and the cathode layer (13) has a set of contact areas (19, 20) that are distributed over a face (15) of said structure (2). A barrier layer (16) hermetically covers said structure (2) and is provided with a set of openings (23, 24) aligned with said set of contact areas (19, 20). A metal conductor (5) has been electroplated on said barrier layer (16) and contacts the set of contact areas (19, 20) via the set of openings (23, 24). A method of forming such a device comprises forming the structure (2), forming the barrier layer (16) with the set of openings (23, 24), and exposing said structure (2) to an electroplating process to form the metal conductor (5).

### FIELD OF THE INVENTION

The present invention relates to an organic diode device comprising: an organic diode structure having an anode layer, a cathode layer and at least one organic layer located between the anode layer and the cathode layer.

The present invention also relates to a method of forming an organic diode device.

### BACKGROUND OF THE INVENTION

Organic diodes include, i.e., organic light emitting diodes and organic photodiodes, also called photovoltaic diodes. Organic Light Emitting Diodes (OLED's) have gained increased attention for use as displays and for illumination purposes. An OLED comprises a layer of a light emitting organic compound located between two thin electrodes. Organic photodiodes have the same principal design as OLED's, except for the fact that photodiodes absorb light and convert it to an electrical current, and find applications in solar cells, photo-sensors etc. A general problem with OLED's is that the electrodes have large resistivity due to their low thickness. In an OLED with a large area this means a large voltage drop over the area and inhomogeneous luminance over the area. What area is large enough to cause a voltage drop depends on the types of materials used, the thickness of the electrodes used, the brightness of the display etc. In general, with present technology, an OLED display larger than a few square centimetres suffer from inhomogeneous luminance. A similar type of voltage drop problem also arises in large area photodiodes.

US 2004/0121508 A1 describes an attempt to solve the above referenced problem. According to this attempt a metal grid is embedded inside one of the thin, transparent electrodes to improve its conductivity. The metal grid is connected to electrical leads by means of a conductive paste or epoxy such that the metal grid may be connected to the voltage supply in order to provide an even voltage distribution also in cases of large area OLED's.

A problem with the OLED of US 2004/0121508 A1 is that it is complicated to manufacture due to the isolated electrical leads, having uninsulated end portions, the electrical leads having to be connected to the metal grid by means of the conductive paste. The large number of electrical leads winding over the surface of the OLED is also not attractive from an esthetical point of view.

### SUMMARY OF THE INVENTION

An object of the present invention is to provide an organic diode device, which is suitable for large area applications, and which avoids the electrical leads provided in the prior art and thus provides for easy manufacturing and an attractive visual appearance.

This object is achieved by an organic diode device comprising:

an organic diode structure having an anode layer, a cathode layer and at least one organic layer located between the anode layer and the cathode layer, one of the anode layer and the cathode layer having a first set of contact areas that are distributed over a first face of said structure,

a barrier layer being located on said first face to hermetically cover said structure, said barrier layer being provided with a first set of openings that are aligned with said first set of contact areas, and

at least one first metal conductor being electroplated on said barrier layer and being in contact with said first set of contact areas via said first set of openings in said barrier layer.

An advantage of this organic diode device is that it provides for even voltage distribution over the area of a large organic diode device and thus an even luminance, or current in the case of a solar cell, over that area. The barrier layer protects the organic diode structure and provides for a long life.

An advantage with the measure according to claim 2 is that the grid makes it possible to divide the surface of the organic diode device in tiles, each of which has an even luminance, or current as the case may be.

An advantage of the measure of claim 3 is that it provides for a high conductivity and yet a low cost for manufacturing.

An advantage of the measure of claim 4 is that it provides for improved electrical contact between the first metal conductor and the anode or cathode layer to which it is connected.

An advantage of the measure according to claim 5 is that it provides for optimum voltage distribution and a very even luminance, or current, over the area of the organic diode device since both the cathode layer and the anode layer are provided with metal conductors. Thus there will be no undesired voltage drops in the anode layer or in the cathode layer.

Another object of the present invention is to provide an efficient way of manufacturing an organic diode device, which is suitable for large area applications.

This object is achieved by a method of forming an organic diode device, the method comprising the steps of:

forming an organic diode structure by providing at least one organic layer between an anode layer and a cathode layer, one of the anode layer and the cathode layer being provided with a first set of contact areas that are distributed over a first face of said structure,

forming a barrier layer on said first face to hermetically cover said structure, said barrier layer being provided with a first set of openings that are aligned with said first set of contact areas, and

exposing said structure, being covered by said barrier layer, to an electroplating process in which said one of the anode layer and the cathode layer is connected to one of the terminals in an electroplating bath such that a conductive metal is electroplated on the first set of contact areas to form at least a first metal conductor at said first face.

An advantage of this method is that it provides for very efficient manufacturing of large area organic diode devices based on OLED or photodiode technology. Thanks to the early application of the barrier layer the organic diode structure is protected from water and oxygen during the further process steps required to form the organic diode device. This makes it possible to use electroplating in a water-based electrolyte for forming the metal conductors without problems of harming the function of the organic diode structure.

An advantage of the embodiment of claim 7 is that the layer of an isolator provides for an efficient way of keeping the metal conductors away from those areas where emission, or absorption, of light is desired. In case of metal conductors being arranged both for the anode layer and the cathode layer the measure according to claim 7 provides for keeping these metal conductors isolated from each other.

An advantage of claim 8 is that removal of the layer of the isolator after the electroplating process provides for increased luminance, or light-absorption, through that face to which the isolator was applied. A further advantage is that any post-processing of the parts located under the layer of the isolator is made easier.

An advantage of the measure according to claim 9 is that it provides for improved conductivity of the anode and/or cathode layer during the electroplating process. This improved conductivity provides for a much increased electroplating rate since the voltage drops being associated with the thin anode layer and cathode layer, this low conductivity being the principal reason of forming the metal conductors in the first place, is avoided by means of the plating base.

An advantage of the measure according to claim 10 is that removing excess portions of the plating base provides for isolating a first metal conductor being located at the first face and connected to the anode layer from a second metal conductor also being located at the first face but connected to the cathode layer.

Further embodiments and advantages of the invention will become apparent from the description below and the appended claims.

### BRIEF DESCRIPTION OF THE DRAWINGS

The invention will now be described in more detail with reference to the appended drawings in which:

FIG. 1 is a top view and shows an organic diode device according to the invention.

FIG. 2 is a schematic cross-section and shows an organic diode device according to the invention as seen in the section II-II shown in FIG. 1.

FIG. 3. is a schematic cross-section and illustrates a first step of a method according to the invention.

FIG. 4. is a schematic cross-section and illustrates a second step of a method according to the invention.

FIG. 5. is a schematic cross-section and illustrates a third step of a method according to the invention.

FIG. 6. is a schematic cross-section and illustrates a fourth step of a method according to the invention.

FIG. 7. is a schematic cross-section and illustrates a fifth step of a method according to the invention.

FIG. 8. is a schematic cross-section and illustrates a sixth step of a method according to the invention.

FIG. 9. is a schematic cross-section and illustrates a seventh step of a method according to the invention.

FIG. 10. is a schematic cross-section and illustrates an organic diode device according to an alternative embodiment of the invention.

### DESCRIPTION OF PREFERRED EMBODIMENTS

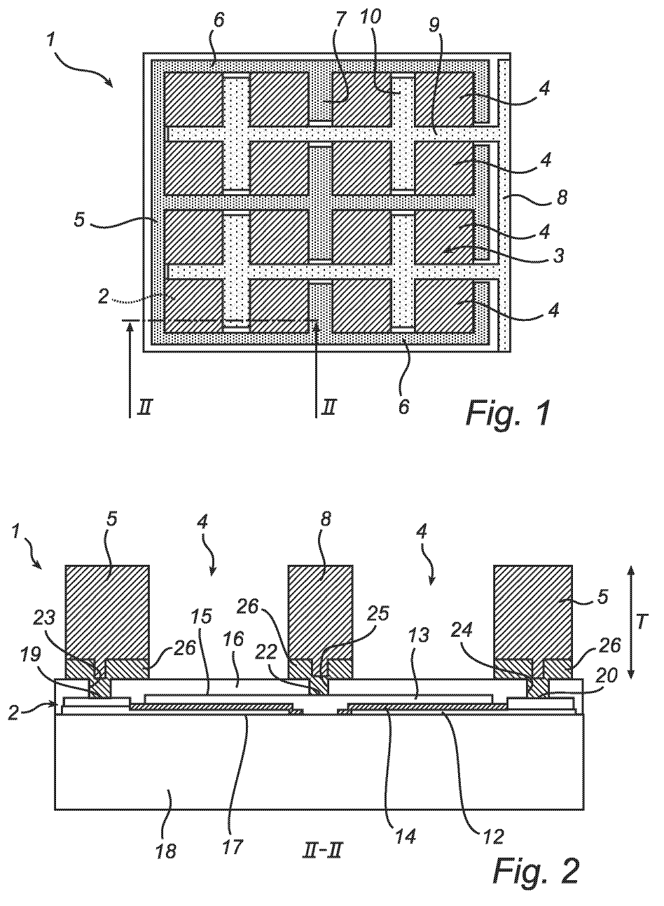

FIG. 1 shows an organic diode device in the form of a light emitting device 1. The light emitting device 1 comprises a light emitting structure 2, which is shown in more detail in FIG. 2. The light emitting device 1 has a large surface 3, which is divided into tiles 4. A first metal conductor 5, which is formed by electroplating as will be described below, forms a first grid on the surface 3. As can be seen in FIG. 1 the first metal conductor 5 comprises stems 6 and branches 7 such that the first metal conductor 5 is in contact with all the tiles 4. A second metal conductor 8, which is formed by electroplating as will be described below, forms a second grid on the surface 3. As can be seen in FIG. 1 the second metal conductor 8 comprises stems 9 and branches 10 such that the second metal conductor 8 is in contact with all of the tiles 4. The first metal conductor 5 and the second metal conductor 8 are isolated from each other. Each of the metal conductors 5, 8 is made of a high conductivity metal, or a mixture of metals, and preferably comprises copper (Cu), silver (Ag), gold (Au), or nickel (Ni), or mixtures thereof.

FIG. 2 schematically illustrates the light emitting device 1 as seen in the cross-section II-II shown in FIG. 1. The light emitting structure 2 comprises an anode layer 12 and a cathode layer 13. The anode layer 12 is made of an at least partly translucent conductive material, such as ITO (Indium Tin Oxide). The anode layer 12 is made of a thin film, which means that the thickness of the anode layer 12 is less than 1 m. Typically the thickness of the anode layer 12, when made of ITO, is 50-200 nm. If transparency is not required the anode layer could be made by a combination of an ITO layer and a metal layer. The cathode layer 13 is made of a thin film of an at least partly translucent material. For instance the cathode layer 13 could be made of a 0.5 nm thin LiF (lithium fluoride) or 5 nm Ba (barium) film on a thin Al (aluminium) film, e.g. 3 nm thick, together with an Ag (silver) film of 10 nm, providing a total thickness of less than 100 nm, preferably 15-50 nm. If transparency is not required the cathode layer could, for example, be made by a combination of a 5 nm Ba film on an Al layer of 300 nm thickness. Between the anode layer 12 and the cathode layer 13 a light emitting organic layer 14 is located. The light emitting organic layer 14 could be any type of organic material, such as a polymer, which emits light upon an applied bias and which is per se known in the art of organic light emitting diodes (OLED's). The thickness of the organic layer 14 is preferably in the same range as that for the anode layer 12. The layer 14 may, as alternative, comprise several organic layers stacked on top of each other.

On a first face 15 of the light emitting structure 2 a barrier layer 16 is located. The barrier layer 16 hermetically covers the first face 15 of the structure 2 and protects it from water, water vapour and oxygen. The barrier layer 16 is made from dielectric materials and may, for instance, comprise a layered structure of SiliconNitride-SiliconOxide-SiliconNitride, also called NON. Further known barrier layers are described by H. Lifka and E. Haskal in WO 2003/050894. Alternative materials for the barrier layer 16 are, for example, silicon carbide, SiC, and alumina, Al₂O₃. As a further alternative stacks of these materials and combinations with organic materials could be used as a barrier layer.

On a second face 17 of the structure 2 a glass plate 18 is located. The glass plate 18 forms the substrate onto which the structure 2 is formed, as will be shown below. The anode layer 12 is provided with a first set of contact areas, of which two contact areas 19, 20 are shown in FIG. 2. The cathode layer 13 is provided with a second set of contact areas, of which a contact area 22 is shown in FIG. 2. In a preferred embodiment cathode material is applied, by e.g. deposition, also to those parts of the anode layer 12 which are to form the contact areas 19, 20. This cathode material is not in electrical contact with the cathode layer 13 itself. The advantage of this embodiment is that both the contact areas 19, 20 of the anode layer 12 and the contact areas 22 of the cathode layer 13 are made of one and the same type of material. This avoids problems of having to work with two different types of material when forming contacts for the anode layer 12 and the cathode layer 13 as will be described below.

The barrier layer 16 is provided with a first set of openings, of which two openings 23, 24 are shown in FIG. 2, that are aligned with the first set of contact areas, e.g. 19, 20, and a second set of openings, of which one opening 25 is shown in FIG. 2, that are aligned with the second set of contact areas, e.g. 22. A contact piece 26 formed from deposited conductive material is located in each of the openings 23, 24, 25 and ensures proper electrical contact between the contact areas 19, 20 of the anode layer 12 and the first metal conductor 5 and between the contact area 22 of the cathode layer 13 and the second metal conductor 8. The contact pieces 26 are preferably made from titanium nitride (TiN) or a stack of TiN and copper (Cu) or of chromium (Cr) and copper. It will be appreciated that the openings 23, 24, 25 in the barrier layer 16 are completely covered by the contact pieces 26 and the metal conductors 5, 8 thus ensuring a proper hermetical covering of the light emitting structure 2.

The thickness T of the first and second metal conductors 5, 8 is preferably in the range of 0.5 to 100 m, still more preferably in the range of 10 to 50 m. Thus the thickness of the metal conductors 5, 8 is about 20 to 100 times larger than that of the anode layer and the cathode layer. Further the metal conductors 5, 8 are made of high conductivity materials, as mentioned above. Thanks to these facts the voltage drop in the grid formed by the first metal conductor 5 and in the grid formed by the second metal conductor 8, as it is shown in FIG. 1, is very limited and thus all tiles 4 of the light emitting device 1 are biased with the same voltage providing an even luminance over the entire area of the light emitting device 1 when in operation. It will be appreciated that the size of each tile 4 is designed such, with respect to the type and thickness of the anode layer, the cathode layer, the organic layer etc., that the voltage drop over the area of the individual tile 4 will be very limited. Thus the present invention overcomes the problems of the prior art in which voltage drops cause an uneven luminance over the area of the light emitting device.

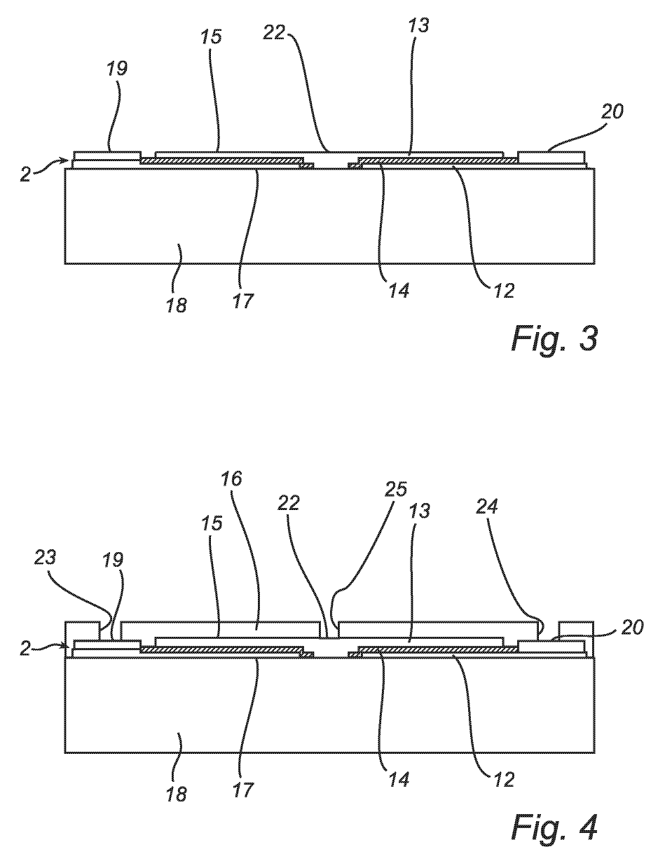

A method of manufacturing the light emitting device 1 will be described with reference to FIG. 3 to FIG. 9.

FIG. 3 illustrates a first step in which the light emitting structure 2 is formed by applying the anode layer 12 onto the glass plate 18, which functions as the substrate. Other materials, such as plastics and metals, may also be used as a substrate. The organic light emitting layer 14 is applied on top of the anode layer 12 and finally the cathode layer 13 is applied on top of the organic layer 14 to complete the structure 2. The structure 2 is designed in such way that the anode layer 12 is provided with a first set of contact areas, represented by contact areas 19 and 20, and that the cathode layer 14 is provided with a second set of contact areas, represented by a contact area 22. The light emitting organic layer 14 is formed as an isolator making it possible for both the first and the second set of contact areas to be present at said first face 15. The first step, illustrated in FIG. 3, could preferably be made by per se known methods of forming organic light emitting diodes (OLED's).

FIG. 4 illustrates a second step in which the barrier layer 16 has been applied to the first face 15 of the structure 2. The barrier layer 16 has, preferably, been deposited by means of plasma deposition. The material in the barrier layer 16 is preferably NON-as described above. As shown in FIG. 4 the barrier layer 16 has a first set of openings, represented by the openings 23, 24 being aligned with said first set of contact areas, 19, 20, and a second set of openings, represented by the opening 25, being aligned with said second set of contact areas, 22. The openings 23, 24, 25 in the barrier layer 16 may be formed by lithography and subsequent etching, by holding a shadow mask above the structure 2 during the deposition, or by another, per se known, technique of forming openings in a thin layer.

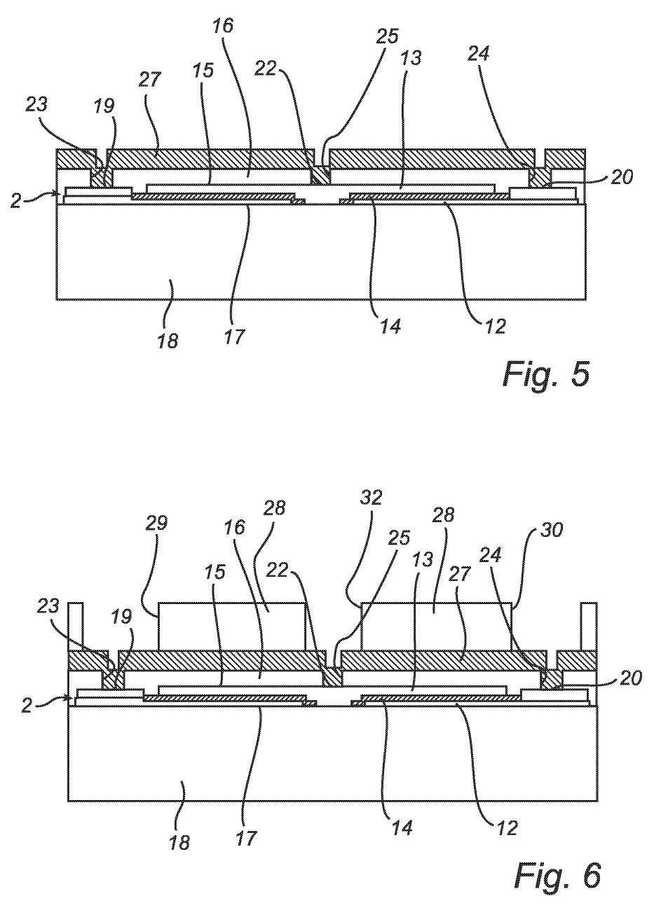

FIG. 5 illustrates a third step in which a plating base 27 is formed as a layer on top of the barrier layer 16 at said first face 15. The purpose of the plating base 27 is to improve the efficiency of the electroplating, described below. It is thus important that the plating base 27 is in contact with the contact areas 19, 20, and 22 via the openings 23, 24, and 25 in the barrier layer 16. According to a particularly preferred embodiment the plating base 27 is deposited in two steps. First TiN is deposited. TiN has the advantage of bonding very well to NON, which is a preferred material in the barrier layer 16, and also to ITO, which is a preferred material in the anode layer 12. Then a metal, such as Cu, is deposited onto the TiN to provide a good conductivity and a good base for the electroplating process, which will be described below. The deposited TiN and Cu form together the plating base 27. The thickness of the plating base 27 is typically in the range of 50-800 nm.

FIG. 6 illustrates a fourth step in which a resist layer 28 has been applied onto the plating base 27. The resist layer 28 has been patterned to provide a first set of holes, represented by holes 29 and 30, being aligned with the first set of contact areas, i.e. the contact areas 19, 20, and a second set of holes, represented by a hole 32, being aligned with the second set of contact areas, i.e. the contact area 22. The patterning of the resist layer 28 could be made by per se known techniques, such as photolithography. In short photolithography includes applying a liquid polymer, using a mask to cure, by illumination, only those portions that are to remain in the pattern, and wash away the uncured polymer to obtain holes in the desired locations.

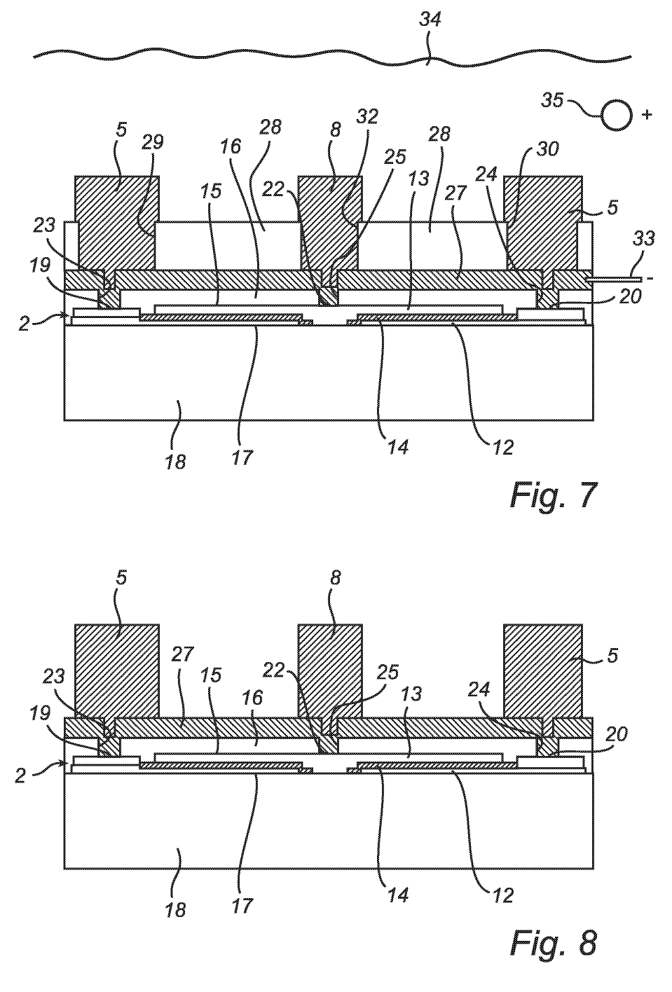

FIG. 7 illustrates a fifth step in which a metal is electroplated to form the first and second metal conductors. This is achieved by connecting the plating base 27 and/or the anode layer 12 and the cathode layer 13 to a first terminal 33, a cathode, of an electrochemical cell. In FIG. 7 the anode layer 12 and the cathode layer 13 are connected to the first terminal 33 via the plating base 27. The structure 2 with the barrier layer 16, the plating base 27 and the resist layer 28 is then lowered into an electroplating bath 34 containing suitable metal ions, such as Cu ions, and a second terminal in the form of an anode 35, and is subjected to an electroplating process, as is schematically indicated in FIG. 7. During the electroplating process the first and second metal conductors 5, 8 will start to grow quite rapidly from the plating base 27 and upwards, as shown in FIG. 7, thanks to the good conductivity of the plating base 27. As shown the resist layer 28 will prevent any growth except for just above the contact areas 19, 20, 22. The application of the resist layer 28 was, in the fourth step, designed so as to cause minimum shielding of the first face 15 by the metal conductors 5, 8 in order to enable light emission through both the first face 15 and the second phase 17, as will be described below. Further the resist layer 28 ensures that the first metal conductor 5 and the second metal conductor 8 are isolated from each other. The barrier layer 16 and the plating base 27 efficiently prevents any contact between the liquid, mainly water, of the electroplating bath 34 and the structure 2 and is a necessity for enabling the use of the electroplating process, since the structure 2 itself is very sensitive to water, as mentioned above. The electroplating process is carried out until the first and second metal conductors 5, 8 have obtained their desired thickness.

FIG. 8 illustrates a sixth step in which the resist layer 28 is removed. Removal of the resist layer 28 could be made by any known method, for example by dissolving the resist layer by means of a suitable solvent. As can be seen in FIG. 8 the plating base 27 is exposed when the resist layer 28 has been removed.

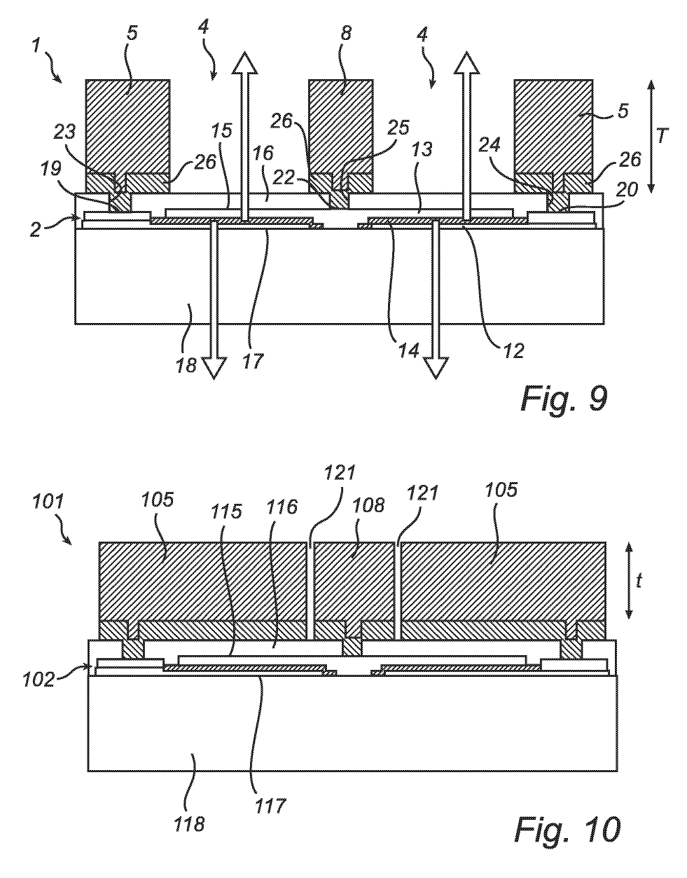

FIG. 9 illustrates a seventh and final step in which those portions of the plating base 27 that are not covered by the first and second metal conductors 5, 8 are etched down to the barrier layer 16 in order to avoid short-circuiting the first metal conductor 5 to the second metal conductor 8. The etching could, thanks to the barrier layer 16, be a wet etching process, which is per se known in the art. Those portions of the plating base 27 that are covered by the metal conductors 5, 8 will not be etched and will form the contact pieces 26 mentioned above. The first metal conductor 5 and the second metal conductor 8 may now be connected to a suitable source of power, not shown, and the light emitting device 1 is ready for use. Optionally, for providing improved protection, a second glass plate, not shown, could be attached, by e.g. gluing it, to said first face 15, i.e. on top of the metal conductors 5, 8. Other materials, such as plastic foils, metals and metal foils, may also be used for protection. Upon the application of a voltage light is, as is indicated by arrows in FIG. 9, emitted via both the first face 15 and via the second face 17. The light emitting device 1 is thus able to emit light in both directions and can be considered to be transparent.

FIG. 10 illustrates a second embodiment of the invention in the form of a light emitting device 101. The light emitting device 101 comprises a light emitting structure 102, which is similar to the structure 2 described above and which is deposited on a glass plate 118. The structure 102 is hermetically covered by a barrier layer 116. The main difference between the light emitting device 101 and the light emitting device 1 is that the light emitting device 101 is not transparent but is adapted to emit light only via its second face 117. Since no light-emission is intended via a first face 115 a broad first metal conductor 105 and a broad second metal conductor 108 may be electroplated on the barrier layer 116. As shown in FIG. 10 there are only small gaps 121 between the first and second metal conductors 105, 108 in order to isolate them from each other. An advantage of the light emitting device 101 is that since the metal conductors 105, 108 are so broad a moderate thickness t is sufficient for providing sufficient conductivity. A further advantage is that the metal conductors 105, 108, covering almost the entire first face 115, assist the barrier layer 116 in hermetically covering the structure 102 and shielding it from oxygen and water vapour. This shielding is particularly important in those areas where the organic layer is not covered by a cathode layer, e.g. in the areas adjacent to the first set of contact areas, i.e. the contact areas related to the anode layer.

It will be appreciated that numerous variants of the above-described embodiments are possible within the scope of the appended patent claims.

Above the invention has been described with reference to an organic diode in the form of an OLED. It will be appreciated that the invention is also applicable to other types of organic diodes. One such example is photodiodes comprising an organic layer, or a stack of organic layers, deposited between two electrodes and adapted for providing an electrical current upon absorption of light. Such photodiodes could be used as photocells and, in particular, large area solar cells. As regards the basic design, and manufacturing method, for a photodiode it is similar to that described above for an OLED.

It is described above that a plating base 27 is deposited on top of the barrier layer 16 prior to the electroplating process. It will be appreciated that the electroplating of the metal conductors 5, 8 could be made also in the absence of the plating base 27. However, in such case the electroplating process would become very slow due to the high resistivity of the anode layer and the cathode layer.

The plating base could preferably be structured before the electroplating step. This structuring of the plating base could be done by several methods, for example by means of shadow mask deposition of the plating base or lithographic/print masking followed by etching and removal of the etch protection. Still another method for structuring a plating base is to use so called lift-off or a similar per se known method in which a resist is deposited in a desired structure and cured. The plating base is then deposited on top of the structured resist. The fact that the plating base has been structured, for example according to one of the methods mentioned just above, has the advantage that during the formation of the conductors by the electroplating step that portion of the plating base which is located on top of the resist will, due to the missing electrical connection, not become covered with the plating metal. Thus the conductors will only be formed on the desired locations. After the electroplating step that portion of the plating base, which is located on top of the resist, can be etched selectively to the electroplated material and thus the metal conductors are formed with the desired shape in an easy manner. Thus the structuring of the plating base, made in order to form a structured plating base layer prior to the electroplating step, makes it easier to electroplate the metal conductors in the desired locations and makes removal of the excess portions of the plating base, after the electroplating step, easier.

Further it is described above that the resist layer 28 is patterned in order to define the locations of the metal conductors 5, 8 and to isolate them from each other. It will be appreciated that it would also be possible to avoid the resist layer and to electroplate a homogenous metal layer, e.g. a copper layer, directly on top of the plating base, or on top of the barrier layer in the absence of a plating base. In an additional step this homogenous copper layer would be etched to provide metal conductors of the desired shape and pattern and isolated from each other. The above-described method of using a resist layer is, however, preferred since the etching of a comparably thick layer of electroplated metal may harm the integrity of the under-lying structures.

In the embodiment described with reference to FIG. 1 and 2 both the anode and the cathode are made from transparent materials. It will be appreciated that in alternative embodiments only the anode or only the cathode could be made transparent, if transparency of the complete organic diode device is not required.

According to the description above the anode layer 12 is placed on the glass plate 18 and has the organic layer 14 and the cathode layer 13 on top of it. It is also possible to form the anode layer and the cathode layer in the reverse order, i.e. to deposit the cathode layer first on the glass plate, then the organic layer and finally the anode layer.

Each of the light emitting devices 1, 101 described above is provided with a first metal conductor 5, 105 connected to the anode layer 12 and a second metal conductor 8, 108 connected to the cathode layer 13. It will be appreciated that it is also possible to design a light emitting device, which has only one metal conductor, which is connected to either the anode layer or the cathode layer. One example is a light emitting device, which is not transparent. In such a case the cathode could be made quite thick providing a sufficient conductivity. The anode, preferably made from ITO, would still be thin and would thus require a first metal conductor to avoid voltage drops.

To summarize an organic diode device 1 comprises an organic diode structure 2 having an anode layer 12, a cathode layer 13 and an organic layer 14. One of the anode layer 12 and the cathode layer 13 has a set of contact areas 19, 20 that are distributed over a face 15 of said structure 2. A barrier layer 16 hermetically covers said structure 2 and is provided with a set of openings 23, 24 aligned with said set of contact areas 19, 20. A metal conductor 5 has been electroplated on said barrier layer 16 and contacts the set of contact areas 19, 20 via the set of openings 23, 24. A method of forming such a device comprises forming the structure 2, forming the barrier layer 16 with the set of openings 23, 24, and exposing said structure 2 to an electroplating process to form the metal conductor 5.

1. An organic diode device comprising:
an organic diode structure (2) having an anode layer (12), a cathode layer (13) and at least one organic layer (14) located between the anode layer (12) and the cathode layer (13), one of the anode layer (12) and the cathode layer (13) having a first set of contact areas (19, 20) that are distributed over a first face (15) of said structure (2),
a barrier layer (16) being located on said first face (15) to hermetically cover said structure (2), said barrier layer (16) being provided with a first set of openings (23, 24) that are aligned with said first set of contact areas (19, 20), and
at least one first metal conductor (5) being electroplated on said barrier layer (16) and being in contact with said first set of contact areas (19, 20) via said first set of openings (23, 24) in said barrier layer (16).

2. An organic diode device according to claim 1, wherein said at least one first metal conductor (5) forms a grid on said first face (15).

3. An organic diode device according to claim 1, wherein said at least one first metal conductor (5) has a thickness (T) of 0.5-100 m.

4. An organic diode device according to claim 1, wherein a plating base (27) has been deposited on said barrier layer (16) to form a contact piece (26) between each of said contact areas (19, 20) and said at least one first metal conductor (5).

5. An organic diode device according to claim 1, wherein said at least one first metal conductor (5) is in contact with the anode layer (12) via said first set of openings (23, 24) in the barrier layer (16), said first set of openings (23, 24) being aligned with said first set of contact areas (19, 20) of the anode layer (12), at least one second metal conductor (8) being electroplated on said barrier layer (16) to contact the cathode layer (13) via a second set of openings (25) in the barrier layer (16), said second set of openings (25) being aligned with a second set of contact areas (22) of the cathode layer (13), the second set of contact areas (22) being distributed over said first face (15), said first and said second metal conductors (5, 8) being isolated from each other.

6. A method of forming an organic diode device comprising the steps of:
forming an organic diode structure (2) by providing at least one organic layer (14) between an anode layer (12) and a cathode layer (13), one of the anode layer (12) and the cathode layer (13) being provided with a first set of contact areas (19, 20) that are distributed over a first face (15) of said structure (2),
forming a barrier layer (16) on said first face (15) to hermetically cover said structure (2), said barrier layer (16) being provided with a first set of openings (23, 24) that are aligned with said first set of contact areas (19, 20), and
exposing said structure (2), being covered by said barrier layer (16), to an electroplating process in which said one of the anode layer (12) and the cathode layer (13) is connected to one of the terminals (33) in an electroplating bath (34) such that a conductive metal is electroplated on the first set of contact areas (19, 20) to form at least a first metal conductor (5) at said first face (15).

7. A method according to claim 6, further comprising, just before the step of exposing said structure (2) to an electroplating process, a step of providing a layer of an isolator (28) to cover those areas of said first face (15) onto which electroplating is not desired.

8. A method according to claim 7, further comprising a step of removing said layer of an isolator (28) after said step of exposing said structure (2) to an electroplating process.

9. A method according to claim 6, further comprising, between the step of forming the barrier layer (16) and the step of exposing said structure (2) to an electroplating process, a step of depositing a layer of a plating base (27) of a conductive material on top of said barrier layer (16) in order to improve the electrical contact between said first set of contact areas (19, 20) and an electrolyte in the electroplating bath (34).

10. A method according to claim 9, further comprising, after said step of exposing said structure (2) to an electroplating process, a step of removing at least a part of those portions of the plating base (27) that are not covered by said at least one first metal conductor (5).

11. A method according to claim 9, wherein the step of depositing a plating base comprises depositing the plating base as a structured layer.
